(19) United States
(12) Patent Application Publication
(10) Pub. No.: US 2025/0212390 A1
(43) Pub. Date: Jun. 26, 2025

(54) SEMICONDUCTOR DEVICE

(71) Applicant: Samsung Electronics Co., Ltd., Suwon-si (KR)

(72) Inventors: Changsik KIM, Suwon-si (KR); Jungun KIM, Suwon-si (KR); Jihee JUN, Suwon-si (KR)

(73) Assignee: Samsung Electronics Co., Ltd., Suwon-si (KR)

(21) Appl. No.: 18/977,490

(22) Filed: Dec. 11, 2024

(30) Foreign Application Priority Data
Dec. 20, 2023 (KR) 10-2023-0187514

(51) Int. Cl. H10B 12/00

(52) U.S. Cl. CPC H10B 12/315; H10B 12/05

(57) ABSTRACT

In order to fulfill excellent performance and economic efficiency, it is desired to increase the integration degree of semiconductor devices. According to the semiconductor device provided in the present inventions, in semiconductor device including a vertical channel transistor, a bit line is configured as a double layer to reduce the contact resistance with respect to a channel layer, and thus, the electrical characteristics and product performance of the semiconductor device may be improved.

### CROSS-REFERENCE TO RELATED APPLICATIONS

This application is based on and claims priority under 35 U.S.C. § 119 to Korean Patent Application No. 10-2023-0187514, filed on Dec. 20, 2023, in the Korean Intellectual Property Office, the disclosure of which is incorporated by reference herein in its entirety.

### BACKGROUND

The inventive concepts relate to semiconductor devices, and more particularly, to semiconductor devices including a vertical channel transistor.

In order to fulfill excellent performance and economic efficiency, it is desired to increase the integration degree of semiconductor devices. In particular, the degree of integration of memory devices is an important factor in determining the economic feasibility of a product. Since the integration degree of a two-dimensional memory device is mainly determined by the area occupied by unit memory cells, the level of technology for forming fine patterns is a decisive factor therefor. However, as expensive equipment is required to form fine patterns and the area of a chip die is limited, although the integration degree of two-dimensional memory devices is increasing, it is still limited.

### SUMMARY

The inventive concepts provide semiconductor devices with improved electrical characteristics and improved product performance.

The objectives to be solved and improved upon by the inventive concepts are not limited to the objectives mentioned above, and other objectives not mentioned will be clearly understood by those skilled in the art from the description below.

According to some aspect of the inventive concepts, there is provided a semiconductor device including a bit line extending in a first horizontal direction on a substrate and including a lower conductive layer and an upper conductive layer, a channel layer in the bit line penetrating a portion of the bit line and having an inner wall and an outer wall, a gate insulating layer on one side of the inner wall of the channel layer, a word line on the gate insulating layer and extending in a second horizontal direction intersecting with the first horizontal direction, and a contact layer extended on an upper surface of the channel layer and an upper surface of the gate insulating layer, the channel layer comprising an oxide semiconductor material containing indium (In), the upper conductive layer comprising a conductive material containing In, and the outer wall of the channel layer is in contact with the upper conductive layer, but not with the lower conductive layer.

According to some aspect of the inventive concepts, there is provided a semiconductor device including a bit line extending in a first horizontal direction on a substrate and including a central conductive layer and a U-shaped conductive layer, a channel layer in the bit line penetrating a portion of the bit line and having sidewalls and a bottom portion, a gate insulating layer on one side of the sidewalls of the channel layer, a word line on the gate insulating layer and extending in a second horizontal direction intersecting with the first horizontal direction, and a contact layer extended on an upper surface of the channel layer and an upper surface of the gate insulating layer, the bottom portion of the channel layer in contact with the U-shaped conductive layer, but not with the central conductive layer, and the U-shaped conductive layer conformally along the bottom portion of the channel layer.

According to some aspect of the inventive concepts, there is provided a semiconductor device including a bit line extending in a first horizontal direction on a substrate and including a first conductive layer containing metal or metal nitride and a second conductive layer containing In, a mold layer covering the bit line on the substrate and defining a mold opening, a channel layer on an inner wall of the mold opening, having a bottom portion penetrating the bit line and a sidewall extending in a vertical direction on the inner wall of the mold opening, and including an oxide semiconductor material containing In, a gate insulating layer on the channel layer within the mold opening and including a high-k dielectric material, a word line within the mold opening and on the gate insulating layer and extending in a second horizontal direction intersecting with the first horizontal direction, a contact layer extended on an upper surface of the channel layer and an upper surface of the gate insulating layer, and a capacitor structure on the contact layer, the bottom portion of the channel layer in contact with the second conductive layer, but not with the first conductive layer.

### BRIEF DESCRIPTION OF THE DRAWINGS

Embodiments will be more clearly understood from the following detailed description taken in conjunction with the accompanying drawings in which:

FIG. 1 illustrates a layout of a semiconductor device according to some example embodiments.

FIG. 2 illustrates an enlarged layout of a portion of a cell array area of FIG. 1.

FIG. 3 is a cross-sectional view taken along line A1-A1′ in FIG. 2.

FIGS. 4 and 5 are cross-sectional views illustrating a semiconductor device according to some example embodiments.

FIGS. 6 to 16 are cross-sectional views illustrating, according to a process sequence, a method of manufacturing a semiconductor device, according to some example embodiments.

FIG. 17 is a structural diagram illustrating a system including a semiconductor device according to some example embodiments.

### DETAILED DESCRIPTION OF THE EMBODIMENTS

Hereinafter, example embodiments of the inventive concepts will be described in detail with reference to the attached drawings.

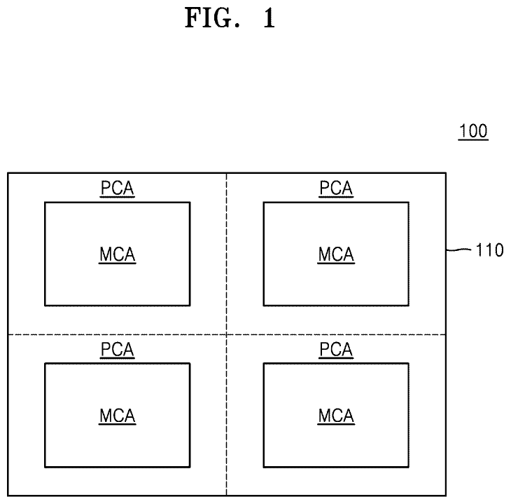

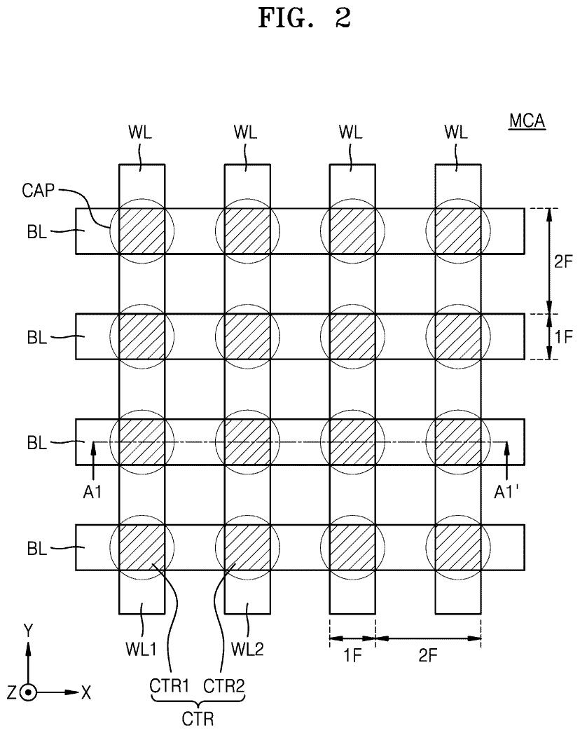

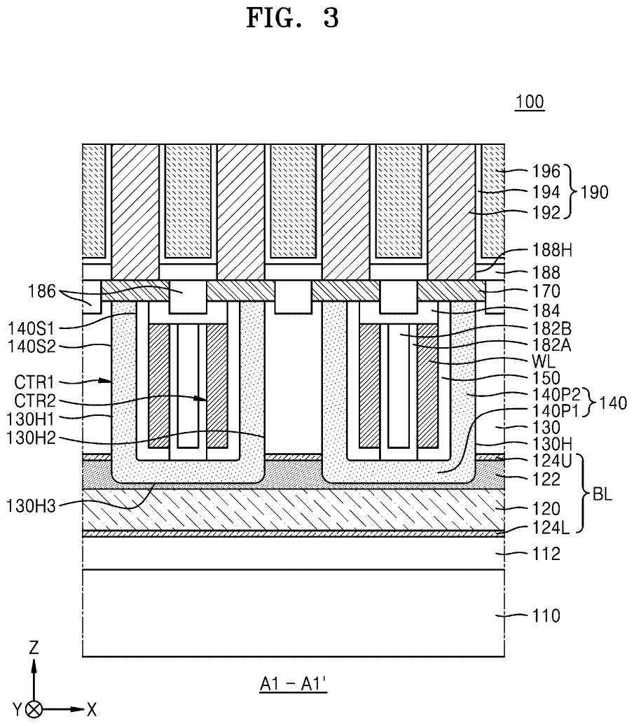

FIG. 1 illustrates a layout of a semiconductor device according to some example embodiments. FIG. 2 illustrates an enlarged layout of a portion of a cell array area of FIG. 1. FIG. 3 is a cross-sectional view taken along line A1-A1′ in FIG. 2.

Referring to FIGS. 1 to 3 together, a semiconductor device 100 may include a substrate 110 including a cell array area MCA and a peripheral circuit area PCA.

In some example embodiments, the cell array area MCA may be a memory cell area of a dynamic random-access memory (DRAM) device, and the peripheral circuit area PCA may be a core area or a peripheral circuit area of the DRAM device. For example, the peripheral circuit area PCA may include a peripheral circuit transistor (not shown) transmitting signals and/or power to a memory cell array included in the cell array area MCA.

In some example embodiments, the peripheral circuit transistor (not shown) may form various circuits such as a command decoder, a control logic, an address buffer, a row decoder, a column decoder, a sense amplifier, and/or a data input/output circuit.

In the cell array area MCA of the substrate 110, a plurality of bit lines BL extending in a first horizontal direction X and a plurality of word lines WL extending in a second horizontal direction Y crossing the first horizontal direction X may be arranged. A plurality of cell transistors CTR may be disposed at intersections between the plurality of bit lines BL and the plurality of word lines WL. A plurality of cell capacitors CAP may be disposed on the plurality of cell transistors CTR, respectively.

The plurality of word lines WL may include a first word line WL1 and a second word line WL2 alternately arranged in the first horizontal direction X, and the plurality of cell transistors CTR may include a first cell transistor CTR1 and a second cell transistor CTR2 arranged alternately in the first horizontal direction X. That is, the first cell transistor CTR1 may be disposed on the first word line WL1, and the second cell transistor CTR2 may be disposed on the second word line WL2.

The first cell transistor CTR1 and the second cell transistor CTR2 may have a mirror image symmetry structure with respect to each other. For example, the first cell transistor CTR1 and the second cell transistor CTR2 may have a mirror image symmetry structure with respect to a center line extending in the second horizontal direction Y.

In some example embodiments, a width of the plurality of bit lines BL may be 1F, and a pitch (for example, the sum of a width and a spacing) of the plurality of bit lines BL may be 2F, herein F being a non-zero distance. Additionally, a width of the plurality of word lines WL may be 1F, and a pitch of the plurality of word lines WL may be 2F. Accordingly, the unit area for forming one cell transistor CTR may be 4F². Accordingly, the cell transistor CTR may have a cross point type that requires a relatively small unit area, which may be advantageous for improving integration of the semiconductor device 100.

A lower insulating layer 112 may be disposed on the substrate 110. In some example embodiments, the substrate 110 may include silicon, for example, single crystalline silicon, polycrystalline silicon, or amorphous silicon. In other embodiments, the substrate 110 may include at least one selected from Ge, SiGe, SiC, GaAs, InAs, and InP. In some example embodiments, the substrate 110 may include a conductive region, for example, a well doped with an impurity or a structure doped with an impurity. Additionally, the lower insulating layer 112 may include, for example, silicon oxide, silicon nitride, or a combination thereof.

A bit line BL extending in the first horizontal direction X may be disposed on the lower insulating layer 112. In some example embodiments, the bit line BL may have a stacked structure including a lower conductive layer 120 and an upper conductive layer 122 disposed on the lower conductive layer 120. Here, the lower conductive layer 120 may be referred to as a first conductive layer, and the upper conductive layer 122 may be referred to as a second conductive layer.

In the semiconductor device 100 according to some example embodiments, the lower conductive layer 120 may include, for example, a metal such as tungsten (W), ruthenium (Ru), or molybdenum (Mo); or metal nitride such as tungsten nitride (WN) and titanium nitride (TiN); or a combination thereof, however, the example embodiments are not limited thereto. Additionally, the upper conductive layer 122 may include a conductive material containing indium (In), for example, any one of indium tin oxide (ITO) and indium oxide (InOₓ), but is not limited thereto.

In some example embodiments, the bit line BL may include a lower conductive barrier layer 124L disposed on a lower surface of the lower conductive layer 120 and an upper conductive barrier layer 124U disposed on an upper surface of the upper conductive layer 124.

In some example embodiments, a thickness of the upper conductive layer 122 in a vertical direction Z may be configured to be less than a thickness of the lower conductive layer 120 in the vertical direction Z.

In some example embodiments, the upper conductive layer 122 may be disposed on an upper surface of the lower conductive layer 120, and the lower conductive barrier layer 124L may be disposed on the lower surface of the lower conductive layer 120, and both the upper surface and the lower surface of the lower conductive layer 120 may be formed in a flat shape. Additionally, the upper conductive barrier layer 124U may be disposed on a portion of the upper surface of the upper conductive layer 122, and the lower conductive layer 120 may be disposed on a lower surface of the upper conductive layer 122, and the upper surface of the upper conductive layer 122 may have a concavo-convex shape, and the lower surface of the upper conductive layer 122 may be formed in a flat shape.

That is, the bit line BL may include a recess area in which a channel layer 140 to be described later is disposed by penetrating the same, and a flat area surrounding the recess area. Here, the recess area of the bit line BL may be formed in the upper conductive barrier layer 124U and the upper conductive layer 122.

A bit line insulating layer (not shown) extending in the first horizontal direction X may be disposed on a sidewall of the bit line BL. For example, the bit line insulating layer may fill a space between two adjacent bit lines BL and may be at the same height as the bit lines BL.

A mold layer 130 may be disposed on the bit line BL and the bit line insulating layer. The mold layer 130 may include a plurality of mold openings 130H. Here, each mold opening 130H may have a first sidewall 130H1 and a second sidewall 130H2 facing each other. Additionally, each mold opening 130H may have a rounded lower wall 130H3 exposing the upper conductive layer 122 of the bit line BL. The recess area may be formed in the bit line BL by the rounded lower wall 130H3 of each mold opening 130H. Additionally, the mold layer 130 may be disposed to cover a flat area surrounding the recess area of the bit line BL. For example, the mold layer 130 may include at least one of silicon oxide, silicon nitride, and silicon oxynitride.

A plurality of channel layers 140 may be disposed on inner walls of the plurality of mold openings 130H. Each of the plurality of channel layers 140 may include a first portion 140P1 extending from the rounded lower wall 130H3 of the plurality of mold openings 130H in the first horizontal direction X and a second portion 140P2 connected to the first portion 140P1 and disposed on the first sidewall 130H1 and the second sidewall 130H2 of the plurality of mold openings 130H.

In some example embodiments, each of the plurality of channel layers 140 may have a U-shaped vertical cross-section that penetrates the bit line BL. The first portion 140P1 of the plurality of channel layers 140 may have a rounded corner. The second portion 140P2 of the plurality of channel layers 140 may include a first sidewall 140S1 and a second sidewall 140S2 that are opposite to each other, and the second sidewall 140S2 may be in contact with the mold layer 130.

Additionally, the first portion 140P1 and the second portion 140P2 of the plurality of channel layers 140 may be in contact with the bit line BL. The first portion 140P1 of the plurality of channel layers 140 may be in contact with the upper conductive layer 122, and a portion of the second portion 140P2 of the plurality of channel layers 140 may be in contact with the upper conductive barrier layer 124U. However, the plurality of channel layers 140 may not be in contact with the lower conductive layer 120 and the lower conductive barrier layer 124L.

In some example embodiments, the plurality of channel layers 140 may include an oxide semiconductor material. In some example embodiments, the oxide semiconductor material may include In, for example, InGaZnOₓ (IGZO), Sn-doped InGaZnOₓ (IGZO), W-doped InGaZnOₓ (IGZO), and IZO (InZnOₓ).

A gate insulating layer 150 and a word line WL may be sequentially disposed on the first sidewall 140S1 of the plurality of channel layers 140. For example, the gate insulating layer 150 may be conformally disposed on an upper surface of the first portion 140P1 and the first sidewall 140S1 of the second portion 140P2 of the plurality of channel layers 140.

The word line WL may be disposed on the upper surface of the first portion 140P1 and the first sidewall 140S1 of the second portion 140P2 of the plurality of channel layers 140, and the gate insulating layer 150 may be disposed between the word line WL and the channel layer 140. Here, the gate insulating layer 150 may include an outer wall facing the first sidewall 140S1 of the plurality of channel layers 140 and an inner wall facing the word line WL.

The channel layer 140 having a U-shaped vertical cross-section may be disposed within one mold opening 130H, and two word lines WL may be arranged apart from each other on the channel layer 140 within one mold opening 130H. Here, one word line WL may be disposed to face one second portion 140P2 of the channel layer 140, and the other word line WL may be disposed to face another second portion 140P2 of the channel layer 140. One word line WL, one second portion 140P2 of the channel layer 140, and the gate insulating layer 150 may constitute a first cell transistor CTR1. Additionally, another word line WL, another second portion 140P2 of the channel layer 140, and the gate insulating layer 150 may constitute a second cell transistor CTR2. Accordingly, the first cell transistor CTR1 and the second cell transistor CTR2 may be arranged in mirror image symmetry to each other within one mold opening 130H.

In some example embodiments, the gate insulating layer 150 may include a high-k dielectric material having a higher dielectric constant than silicon oxide. In some example embodiments, the gate insulating layer 150 may have a dielectric constant of about or exactly 10 to about or exactly 25. For example, the gate insulating layer 150 may include HfO₂, Al₂O₃, HfAlO₃, Ta₂O₃, TiO₂, or a combination thereof, but is not limited thereto.

In some example embodiments, the word line WL may include Ti, TiN, Ta, TaN, W, WN, TiSiN, WSiN, polysilicon, or a combination thereof.

The contact layer 170 may be disposed on an upper surface of the channel layer 140 and an upper surface of the gate insulating layer 150. The contact layer 170 may cover the channel layer 140 and the gate insulating layer 150 and may extend onto the mold layer 130. The contact layer 170 may include Ti, TiN, Ta, TaN, W, WN, TiSiN, WSiN, polysilicon, or a combination thereof.

An insulating liner 182A and a first insulating layer 182B may be disposed between two word lines WL within each of the plurality of mold openings 130H, and a second insulating layer 184 may be disposed on the two word lines WL. Additionally, a third insulating layer 186 may be disposed on both sidewalls of the contact layer 170. For example, the insulating liner 182A may include silicon nitride, and the first insulating layer 182B may include silicon oxide. Additionally, the second insulating layer 184 and the third insulating layer 186 may include silicon nitride.

An etch stop layer 188 may be disposed on the contact layer 170 and the third insulating layer 186. The etch stop layer 188 may include an opening 188H, and an upper surface of the contact layer 170 may be exposed through the opening 188H.

A capacitor structure 190 may be disposed on the etch stop layer 188. The capacitor structure 190 may include a lower electrode 192, a capacitor dielectric layer 194, and an upper electrode 196. A sidewall of a bottom portion of the lower electrode 192 may be disposed within the opening 188H of the etch stop layer 188, and the lower electrode 192 may extend in the vertical direction Z. The capacitor dielectric layer 194 may be disposed on a sidewall of the lower electrode 192, and the upper electrode 196 may cover the capacitor dielectric layer 194 on the lower electrode 192.

In order to fulfill excellent performance and economic efficiency, it is required to increase the integration degree of semiconductor devices. In particular, the degree of integration of memory devices is an important factor in determining the economic feasibility of a product. Since the integration degree of a two-dimensional memory device is mainly determined by the area occupied by unit memory cells, the level of technology for forming fine patterns is a decisive factor therefor. However, as expensive equipment is required to form fine patterns and the area of a chip die is limited, although the integration degree of two-dimensional memory devices is increasing, it is still limited. Accordingly, the demand for semiconductor devices including a vertical channel transistor (VCT) is increasing.

Generally, in a semiconductor device that uses an oxide semiconductor material containing In as a channel layer constituting a vertical channel transistor, due to significant differences in the properties between the material constituting the channel layer (oxide semiconductor material) and the material constituting a bit line (metal or metal nitrides), contact resistance increases and electrical characteristics such as on current may deteriorate. Accordingly, problems such as decrease in product reliability may occur in semiconductor devices.

To solve problems such as the above, in the semiconductor device 100 according to the inventive concepts, the bit line BL may be formed in a stacked structure, and in particular, a conductive material including In, which is a material constituting the channel layer 140, may be used to form the upper conductive layer 122, so as to reduce contact resistance on a contact surface between the channel layer 140 and the upper conductive layer 122 for the first time, and contact resistance on a contact surface between the upper conductive layer 122 and the lower conductive layer 120 may be reduced for the second time. Accordingly, the overall resistance of the bit line BL may be lowered, and electrical characteristics such as on-current may be improved.

Ultimately, the semiconductor device 100 having improved electrical characteristics and product performance may be provided by forming the bit line BL in a stacked structure of the lower conductive layer 120 and the upper conductive layer 122 including different conductive materials.

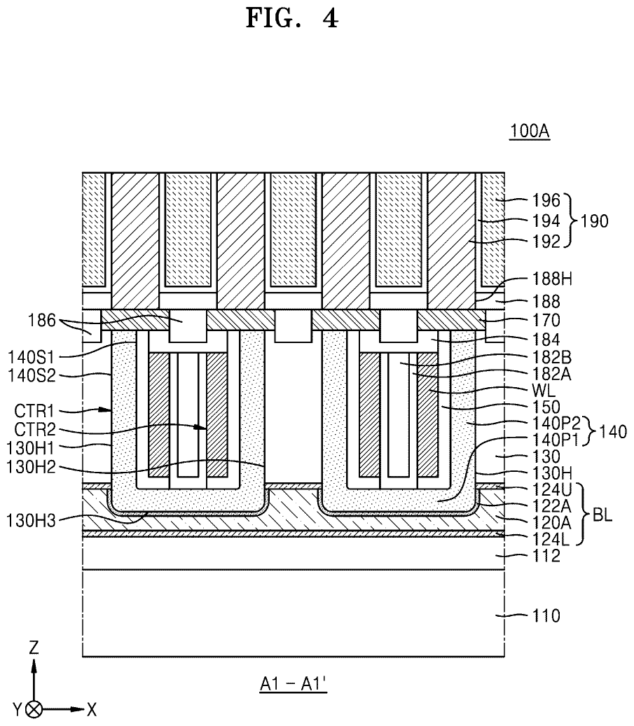

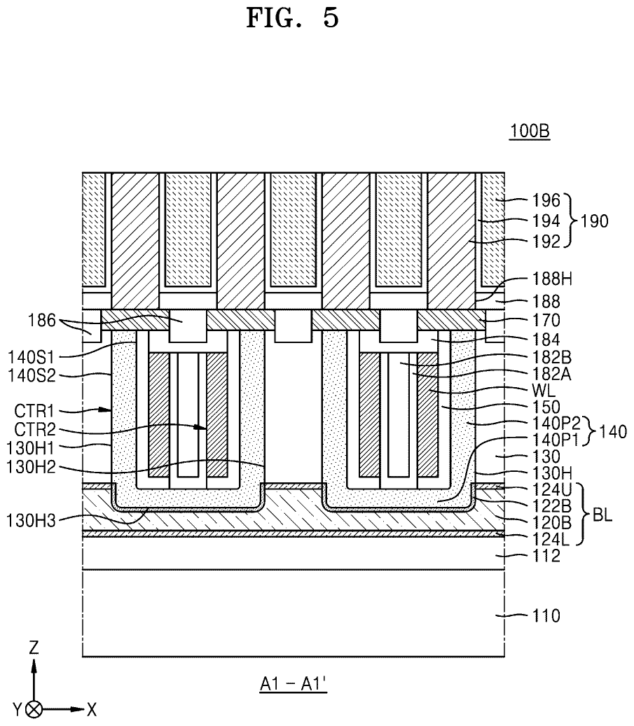

FIGS. 4 and 5 are cross-sectional views illustrating a semiconductor device according to some example embodiments.

Most of the components constituting semiconductor devices 100A and 100B described below and the materials forming the components are substantially the same or similar to those previously described with reference to FIGS. 1 to 3. Thus, for convenience of description, the description will focus on differences from the semiconductor device 100 described above.

Referring to FIG. 4, the semiconductor device 100A may include a bit line BL including a central conductive layer 120A and a U-shaped conductive layer 122A, a word line WL, a channel layer 140, a gate insulating layer 150, a contact layer 170, and a capacitor structure 190.

In the semiconductor device 100A according to some example embodiments, the bit line BL extending in the first horizontal direction X may be disposed on the lower insulating layer 112. In some example embodiments, the bit line BL may include the central conductive layer 120A and the U-shaped conductive layer 122A disposed on a portion of the central conductive layer 120A. The central conductive layer 120A may include a recess area, and the U-shaped conductive layer 122A may be conformally disposed to be in contact with an inner wall of the recess area of the central conductive layer 120A. Here, the central conductive layer 120A may be referred to as a first conductive layer, and the U-shaped conductive layer 122A may be referred to as a second conductive layer.

In the semiconductor device 100A according to some example embodiments, the central conductive layer 120A may include, for example, a metal such as tungsten (W), ruthenium (Ru), or molybdenum (Mo); or metal nitride such as tungsten nitride (WN) and titanium nitride (TiN); or a combination thereof, however, the example embodiments are not limited thereto. Additionally, the U-shaped conductive layer 122A may include a conductive material containing In, for example, any one of indium tin oxide (ITO) and indium oxide (InOₓ), but is not limited thereto.

In some example embodiments, the bit line BL may include a lower conductive barrier layer 124L disposed on a lower surface of the central conductive layer 120A and an upper conductive barrier layer 124U disposed on a portion of an upper surface of the central conductive layer 120A. Here, an uppermost surface of the U-shaped conductive layer 122A may be disposed to be in contact with a lowermost surface of the upper conductive barrier layer 124U.

In some example embodiments, each of the plurality of channel layers 140 may have a U-shaped vertical cross-section that penetrates the bit line BL. The first portion 140P1 of the plurality of channel layers 140 may have a rounded corner. The U-shaped conductive layer 122A may be conformally disposed along the rounded shape of the first portion 140P1 of the plurality of channel layers 140. The second portion 140P2 of the plurality of channel layers 140 may include a first sidewall 140S1 and a second sidewall 140S2 that are opposite to each other, and the second sidewall 140S2 may be in contact with the mold layer 130.

Additionally, the first portion 140P1 and the second portion 140P2 of the plurality of channel layers 140 may contact the bit line BL. The first portion 140P1 of the plurality of channel layers 140 may be in contact with the U-shaped conductive layer 122A, and a portion of the second portion 140P2 of the plurality of channel layers 140 may be in contact with the upper conductive barrier layer 124U. However, the plurality of channel layers 140 may not be in contact with the lower conductive barrier layer 124L. In other words, the U-shaped conductive layer 122A may be disposed along an interface between the plurality of channel layers 140 and the central conductive layer 120A.

Referring to FIG. 5, the semiconductor device 100B may include a bit line BL including a central conductive layer 120B and a U-shaped conductive layer 122B, a word line WL, a channel layer 140, a gate insulating layer 150, a contact layer 170, and a capacitor structure 190.

In the semiconductor device 100B according to some example embodiments, the bit line BL extending in the first horizontal direction X may be disposed on the lower insulating layer 112. In some example embodiments, the bit line BL may include the central conductive layer 120B and the U-shaped conductive layer 122B disposed on a portion of the central conductive layer 120B. The central conductive layer 120B may include a recess area, and the U-shaped conductive layer 122B may be conformally disposed to be in contact with an inner wall of the recess area of the central conductive layer 120B. Here, the central conductive layer 120B may be referred to as a first conductive layer, and the U-shaped conductive layer 122B may be referred to as a second conductive layer.

In the semiconductor device 100B according to some example embodiments, the central conductive layer 120B may include, for example, a metal such as tungsten (W), ruthenium (Ru), or molybdenum (Mo); or metal nitride such as tungsten nitride (WN) and titanium nitride (TiN); or a combination thereof, however, the example embodiments are not limited thereto. Additionally, the U-shaped conductive layer 122B may include a conductive material containing In, for example, any one of indium tin oxide (ITO) and indium oxide (InOₓ), but is not limited thereto.

In some example embodiments, the bit line BL may include a lower conductive barrier layer 124L disposed on a lower surface of the central conductive layer 120B and an upper conductive barrier layer 124U disposed on a portion of an upper surface of the central conductive layer 120B. Here, a sidewall of the U-shaped conductive layer 122B may be disposed to be in contact with a sidewall of the upper conductive barrier layer 124U.

In some example embodiments, each of the plurality of channel layers 140 may have a U-shaped vertical cross-section that penetrates the bit line BL. The first portion 140P1 of the plurality of channel layers 140 may have a rounded corner. The U-shaped conductive layer 122B may be conformally disposed along the rounded shape of the first portion 140P1 of the plurality of channel layers 140. The second portion 140P2 of the plurality of channel layers 140 may include a first sidewall 140S1 and a second sidewall 140S2 that are opposite to each other, and the second sidewall 140S2 may be in contact with the mold layer 130. However, due to the U-shaped conductive layer 122B, a step may be formed at a connection portion between the first portion 140P1 and the second portion 140P2 of the plurality of channel layers 140.

Additionally, the first portion 140P1 and the second portion 140P2 of the plurality of channel layers 140 may contact the bit line BL. The first portion 140P1 of the plurality of channel layers 140 may be in contact with the U-shaped conductive layer 122B, and a portion of the second portion 140P2 of the plurality of channel layers 140 may be in contact with the upper conductive barrier layer 124U. In some example embodiments, as shown in FIG. 5, the U-shaped conductive layer 122B may be completely between the second portion 140P2 and the upper conductive barrier layer 124U, however, in some example embodiments, the U-shaped conductive layer 122B may not extend fully between the second portion 140P2 and the upper conductive barrier layer 124U and thereby and a portion of the second portion 140P2 of the plurality of channel layers 140 may be in contact with the upper conductive barrier layer 124U. However, the plurality of channel layers 140 may not be in contact with the lower conductive barrier layer 124L. In other words, the U-shaped conductive layer 122B may be disposed along the interface between the plurality of channel layers 140 and the central conductive layer 120B.

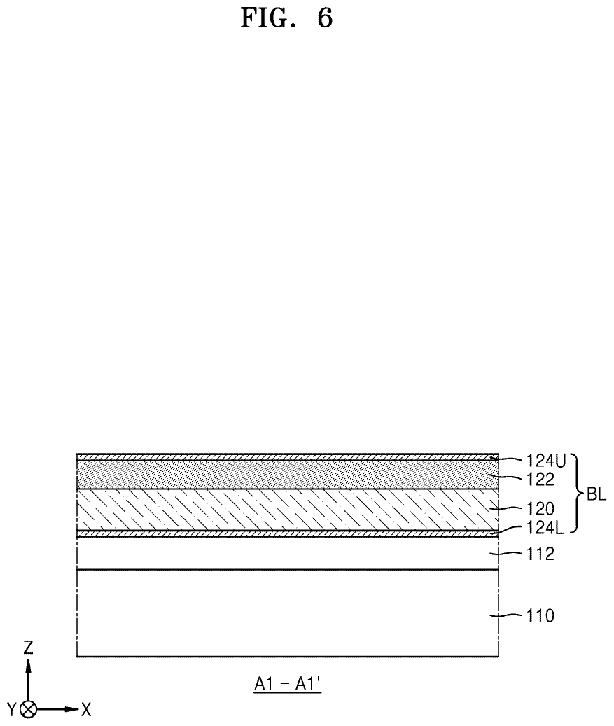

FIGS. 6 to 16 are cross-sectional views illustrating, according to a process sequence, a method of manufacturing a semiconductor device, according to some example embodiments.

Referring to FIG. 6, a lower insulating layer 112 may be formed on a substrate 110.

Next, a plurality of bit lines BL extending in a first horizontal direction X and a bit line insulating layer (not shown) which fills a space between the plurality of bit lines BL may be formed on the lower insulating layer 112.

In some example embodiments, each of the plurality of bit lines BL may have a stack structure including the lower conductive barrier layer 124L, the lower conductive layer 120, the upper conductive layer 122, and the upper conductive barrier layer 124U arranged sequentially. For example, a bit line formation space (not shown) may be formed by forming the bit line insulating layer on the lower insulating layer 112 and patterning the bit line insulating layer by using a mask pattern (not shown), and the lower conductive barrier layer 124L, the lower conductive layer 120, the upper conductive layer 122, and the upper conductive barrier layer 124U may be sequentially formed in the bit line formation space.

Next, the plurality of bit lines BL may be formed by removing the lower conductive barrier layer 124L, the lower conductive layer 120, the upper conductive layer 122, and an upper portion of the upper conductive barrier layer 124U so that an upper surface of the bit line insulating layer is exposed.

The lower conductive layer 120 may include, for example, a metal such as tungsten (W), ruthenium (Ru), or molybdenum (Mo) or metal nitride such as tungsten nitride (WN) or titanium nitride (TiN); or a combination thereof. Additionally, the upper conductive layer 122 may include a conductive material containing In, for example, any one of indium tin oxide (ITO) and indium oxide (InOₓ).

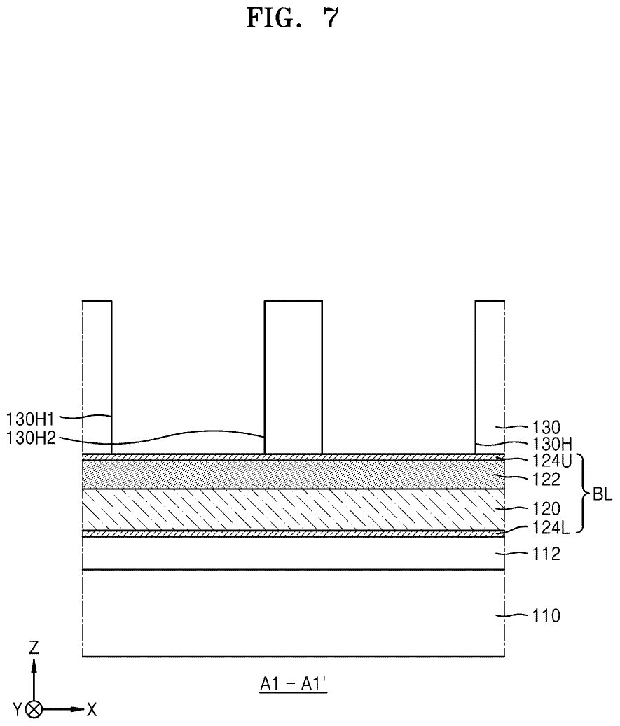

Referring to FIG. 7, a mold layer 130 including a mold opening 130H may be formed on the plurality of bit lines BL and the bit line insulating layer.

The mold layer 130 may be formed using at least one of silicon oxide, silicon nitride, and silicon oxynitride and have a relatively large height in the vertical direction Z.

Next, a mask pattern (not shown) may be formed on the mold layer 130, and a plurality of mold openings 130H may be formed using the mask pattern as an etch mask. Each mold opening 130H may have a first sidewall 130H1 and a second sidewall 130H2 facing each other.

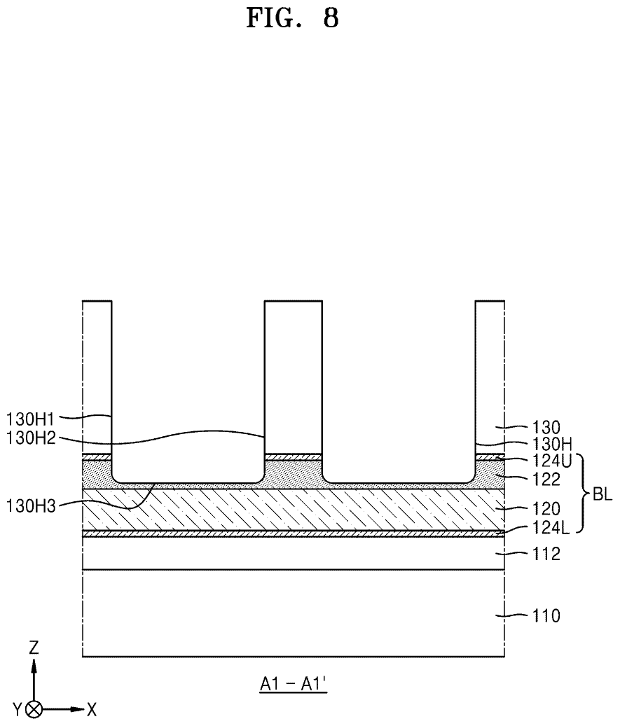

Referring to FIG. 8, the upper conductive barrier layer 124U and the upper conductive layer 122 of the bit line BL exposed through the mold opening 130H may be etched to form a rounded lower wall 130H3.

A recess area may be formed in the bit line BL by the rounded lower wall 130H3 of each mold opening 130H. The bit line BL may include a recess area and a flat area surrounding the recess area. Here, the recess area of the bit line BL may be formed only in the upper conductive barrier layer 124U and the upper conductive layer 122.

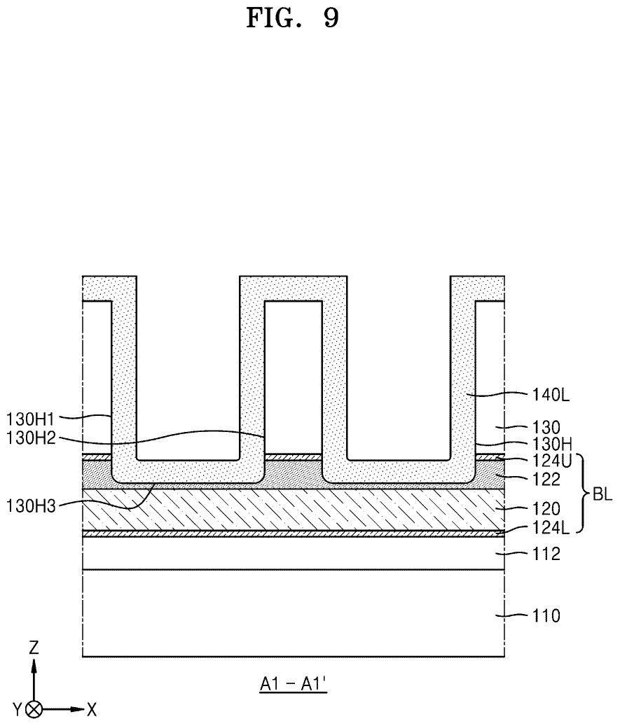

Referring to FIG. 9, a preliminary channel layer 140L may be formed on the mold layer 130 to conformally cover the inner wall of the mold opening 130H.

The preliminary channel layer 140L may be formed using an oxide semiconductor material. The oxide semiconductor material may include In, for example, InGaZnOₓ (IGZO), Sn-doped InGaZnOₓ (IGZO), W-doped InGaZnOₓ (IGZO), and InZnOₓ (IZO).

In some example embodiments, the preliminary channel layer 140L may be formed using at least one of a chemical vapor deposition (CVD) process, a low pressure CVD process, a plasma enhanced CVD process, a metal organic CVD (MOCVD) process, and/or an atomic layer deposition process.

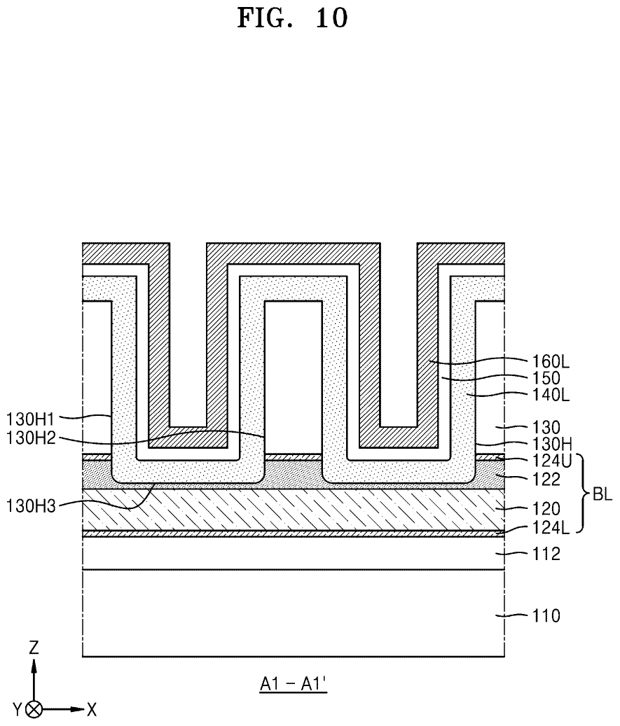

Referring to FIG. 10, a gate insulating layer 150 and a gate electrode layer 160L may be sequentially formed on the preliminary channel layer 140L.

The gate insulating layer 150 may include a high-k dielectric material having a higher dielectric constant than silicon oxide. In some example embodiments, the gate electrode layer 160L may be formed using Ti, TiN, Ta, TaN, W, WN, TiSiN, WSiN, polysilicon, or a combination thereof.

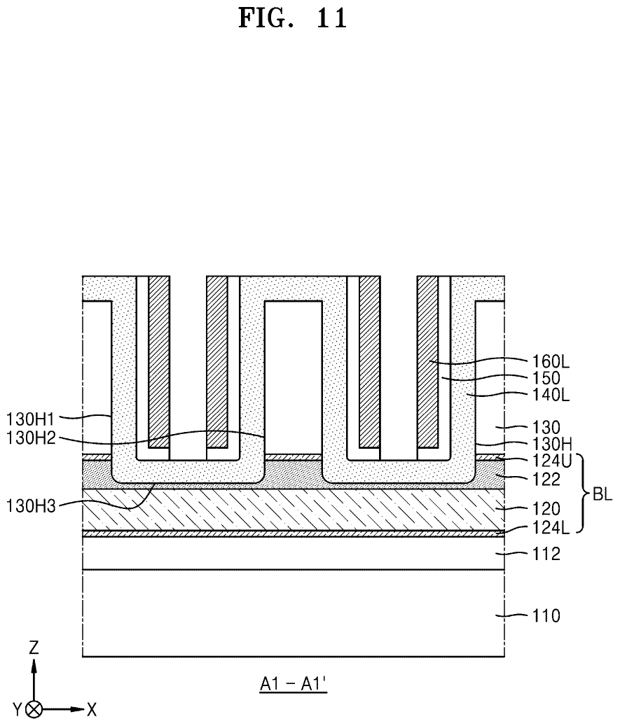

Referring to FIG. 11, an anisotropic etching process may be performed on the gate electrode layer 160L to remove a portion of the gate electrode layer 160L disposed on a bottom portion of the mold opening 130H and the gate electrode layer 160L may be left on the first sidewall 130H1 and the second sidewall 130H2 of the mold opening 130H.

Meanwhile, a portion of the gate electrode layer 160L disposed on an upper surface of the mold layer 130 may be removed by the anisotropic etching process.

For example, the gate electrode layer 160L may be divided into two word lines WL respectively disposed on the first sidewall 130H1 and the second sidewall 130H2 of the plurality of mold openings 130H.

Meanwhile, a portion of the gate insulating layer 150 disposed on the bottom portion of the mold opening 130H may be removed by the anisotropic etching process. As a result, an upper surface of the preliminary channel layer 140L may be exposed on the bottom portion of the mold opening 130H. Additionally, by the anisotropic etching process, a portion of the gate insulating layer 150 disposed on the upper surface of the mold layer 130 may be removed and the upper surface of the preliminary channel layer 140L may be exposed.

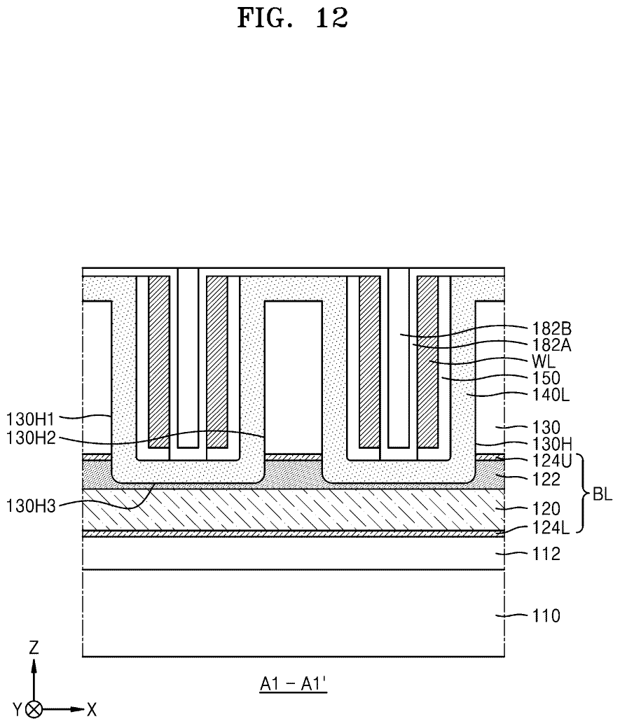

Referring to FIG. 12, an insulating liner 182A and a first insulating layer 182B may be formed inside the mold opening 130H.

The insulating liner 182A and the first insulating layer 182B may be disposed between two adjacent word lines WL, and the insulating liner 182A may be disposed on the upper surface of the preliminary channel layer 140L.

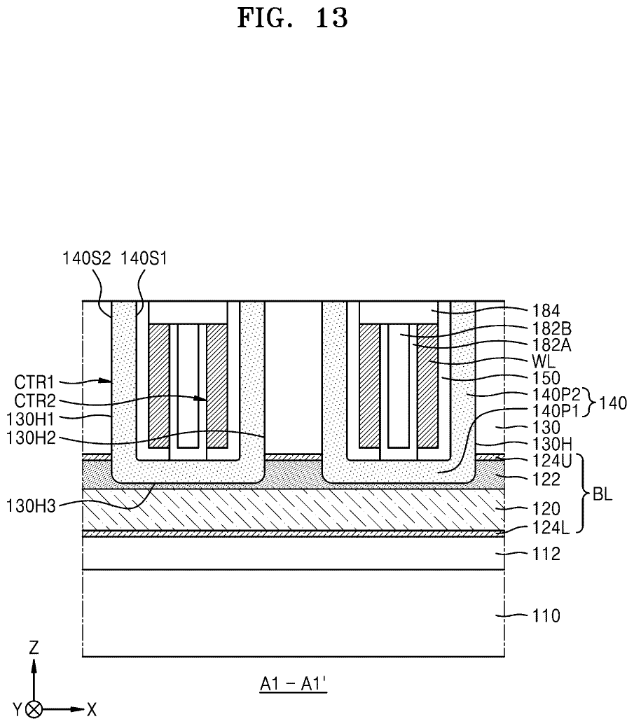

Referring to FIG. 13, the insulating liner 182A and a portion of the preliminary channel layer 140L disposed on the upper surface of the mold layer 130 may be removed by an etch-back process or a planarization process to form the channel layer 140 within the mold opening 130H.

The channel layer 140 having a U-shaped vertical cross-section may be formed within the mold opening 130H through the etch-back process or the planarization process. Additionally, as the portion of the preliminary channel layer 140L disposed on the upper surface of the mold layer 130 is removed, the upper surface of the mold layer 130 may be exposed.

In some example embodiments, the channel layer 140 may include the first portion 140P1 extending in the first horizontal direction X and the second portion 140P2 connected to both ends of the first portion 140P1 and extending in the vertical direction Z. A first sidewall 140S1 of the second portion 140P2 may be surrounded by the gate insulating layer 150, and a second sidewall 140S2 of the second portion 140P2 may be surrounded by the mold layer 130. Additionally, an upper surface of the channel layer 140 may be at the same vertical level as the upper surface of the mold layer 130.

Next, an upper portion of the word line WL disposed within the mold opening 130H may be removed through an etch-back process. In the etch-back process, an upper portion of the insulating liner 182A and an upper portion of the first insulating layer 182B may be removed together.

Next, the second insulating layer 184 may be formed to fill the entrance of the mold opening 130H. The second insulating layer 184 may be disposed with a flat bottom surface on upper surfaces of the word line WL, the insulating liner 182A, and the first insulating layer 182B.

Accordingly, the first cell transistor CTR1 and the second cell transistor CTR2 may be formed within the mold opening 130H. The first cell transistor CTR1 and the second cell transistor CTR2 may be arranged in mirror image symmetry with respect to each other.

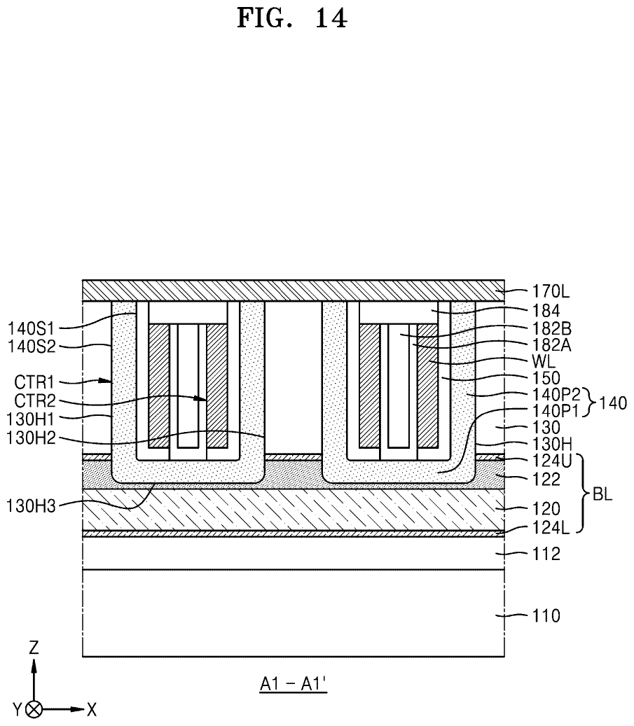

Referring to FIG. 14, a contact conductive layer 170L may be formed on the mold layer 130 and the second insulating layer 184.

In some example embodiments, the contact conductive layer 170L may include Ti, TiN, Ta, TaN, W, WN, TiSiN, WSiN, polysilicon, or a combination thereof.

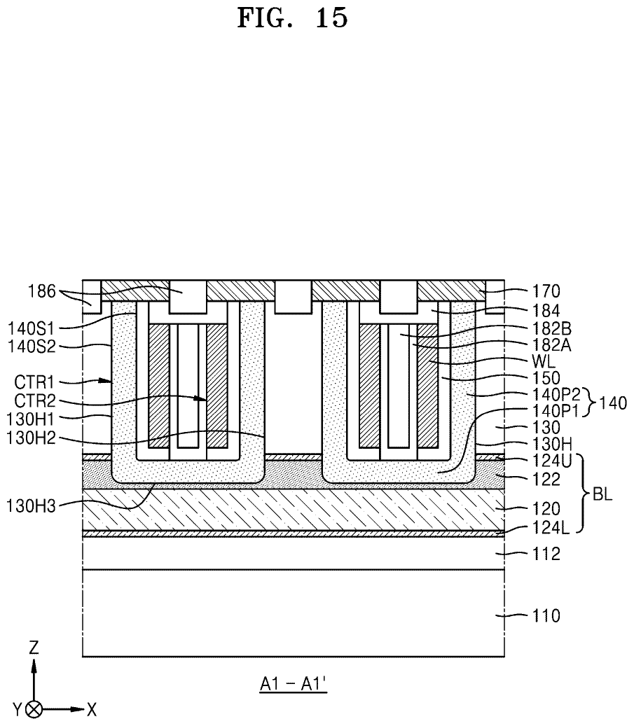

Referring to FIG. 15, a mask pattern (not shown) may be formed on the contact conductive layer 170L (see FIG. 14), and a portion of the contact conductive layer 170L, a portion of the mold layer 130, and a portion of the second insulating layer 184 may be removed using the mask pattern to form the contact layer 170, and the third insulating layer 186 may be formed in a region from which the contact conductive layer 170L has been removed.

In some example embodiments, the third insulating layer 186 may be formed using silicon nitride. In addition, a sidewall of the contact layer 170 may be surrounded by the third insulating layer 186, and a bottom surface of the contact layer 170 may cover the upper surface of the channel layer 140 and the upper surface of the gate insulating layer 150 to extend onto the mold layer 130.

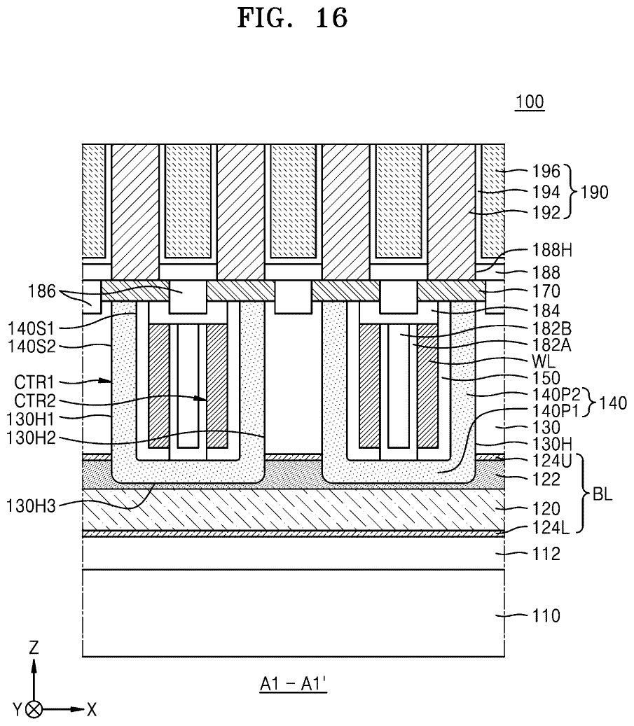

Referring to FIG. 16, the etch stop layer 188 may be formed on the contact layer 170 and the third insulating layer 186. The etch stop layer 188 may include an opening 188H, and the upper surface of the contact layer 170 may be exposed through the opening 188H.

Next, a lower electrode 192, a capacitor dielectric layer 194, and an upper electrode 196 may be sequentially formed on the etch stop layer 188.

By performing the manufacturing process described above, the semiconductor device 100 according to the inventive concepts may be manufactured.

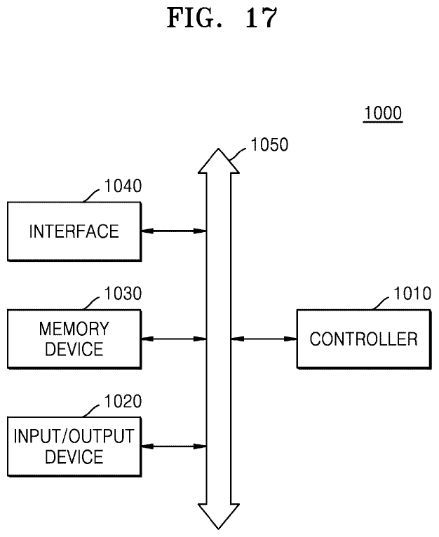

FIG. 17 is a structural diagram illustrating a system including a semiconductor device according to some example embodiments.

Referring to FIG. 17, a system 1000 includes a controller 1010, an input/output device 1020, a memory device 1030, an interface 1040, and a bus 1050.

The system 1000 may be a mobile system or a system that transmits or receives information. In some example embodiments, the mobile system may be a portable computer, a web tablet, a mobile phone, a digital music player, or a memory card.

The controller 1010 is for controlling an execution program in the system 1000 and may include a microprocessor, a digital signal processor, a microcontroller, or a similar device.

The input/output device 1020 may be used to input or output data of the system 1000. The system 1000 may be connected to an external device, for example, a personal computer or a network, using the input/output device 1020, and may exchange data with the external device. The input/output device 1020 may be, for example, a touch screen, a touch pad, a keyboard, or a display.

The memory device 1030 may store data for the operation of the controller 1010 or store data processed by the controller 1010. The memory device 1030 may include any one of the semiconductor devices 100, 100A, and 100B according to the inventive concepts described above.

The interface 1040 may be a data transmission path between the system 1000 and an external device. The controller 1010, the input/output device 1020, the memory device 1030, and the interface 1040 may communicate with each other via the bus 1050.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

While the inventive concepts have been particularly shown and described with reference to example embodiments thereof, it will be understood by those skilled in the art that various changes in form and details may be made therein without departing from the spirit and scope of the inventive concepts as defined by the appended claims. The example embodiments should thus be considered in a descriptive sense only and not for purposes of limitation.

While the inventive concepts have been particularly shown and described with reference to example embodiments thereof, it will be understood that various changes in form and details may be made therein without departing from the spirit and scope of the following claims.

What is claimed is:

1. A semiconductor device comprising:
a bit line extending in a first horizontal direction on a substrate and including a lower conductive layer and an upper conductive layer;
a channel layer in the bit line penetrating a portion of the bit line and having an inner wall and an outer wall;
a gate insulating layer on one side of the inner wall of the channel layer;
a word line on the gate insulating layer and extending in a second horizontal direction intersecting with the first horizontal direction; and
a contact layer extended on an upper surface of the channel layer and an upper surface of the gate insulating layer,
the channel layer comprising an oxide semiconductor material containing indium (In),
the upper conductive layer comprising a conductive material containing In, and
the outer wall of the channel layer is in contact with the upper conductive layer, but not with the lower conductive layer.

2. The semiconductor device of claim 1, wherein
the channel layer comprises one of InGaZnOₓ (IGZO) and InZnOₓ (IZO),
the upper conductive layer comprises one of indium tin oxide (ITO) and indium oxide (InOₓ), and
the lower conductive layer comprises metal or metal nitride.

3. The semiconductor device of claim 1, wherein
an upper surface of the upper conductive layer has a concavo-convex shape,
a lower surface of the upper conductive layer has a flat shape, and
both an upper surface and a lower surface of the lower conductive layer are flat.

4. The semiconductor device of claim 3, wherein a thickness of the upper conductive layer in a vertical direction is less than a thickness of the lower conductive layer in the vertical direction.

5. The semiconductor device of claim 4, wherein
the channel layer has a U-shape that penetrates a portion of the upper conductive layer, and
a portion of the outer wall of the channel layer in contact with the upper conductive layer has rounded corners.

6. The semiconductor device of claim 1, wherein
the bit line further includes a lower conductive barrier layer on a lower surface of the lower conductive layer and an upper conductive barrier layer on an upper surface of the upper conductive layer, and
the outer wall of the channel layer contacts a sidewall of the upper conductive barrier layer and the upper conductive layer, but not the lower conductive layer and the lower conductive barrier layer.

7. The semiconductor device of claim 6, wherein
the bit line includes a recess area and a flat area surrounding the recess area,
the semiconductor device further comprises a mold layer covering the flat area of the bit line, and
the outer wall of the channel layer is in contact with a sidewall of the mold layer and the recess area of the bit line.

8. The semiconductor device of claim 7, wherein the recess area of the bit line is formed in the upper conductive barrier layer and the upper conductive layer.

9. A semiconductor device comprising:
a bit line extending in a first horizontal direction on a substrate and including a central conductive layer and a U-shaped conductive layer;
a channel layer in the bit line penetrating a portion of the bit line and having sidewalls and a bottom portion;
a gate insulating layer on one side of the sidewalls of the channel layer;
a word line on the gate insulating layer and extending in a second horizontal direction intersecting with the first horizontal direction; and
a contact layer extended on an upper surface of the channel layer and an upper surface of the gate insulating layer,
the bottom portion of the channel layer in contact with the U-shaped conductive layer, but not with the central conductive layer, and
the U-shaped conductive layer conformally along the bottom portion of the channel layer.

10. The semiconductor device of claim 9, wherein
the channel layer comprises an oxide semiconductor material containing indium (In), and
the U-shaped conductive layer comprises a conductive material containing In.

11. The semiconductor device of claim 10, wherein
the channel layer comprises one of InGaZnOₓ (IGZO) and InZnOₓ (IZO), and
the U-shaped conductive layer comprises one of indium tin oxide (ITO) and indium oxide (InOₓ).

12. The semiconductor device of claim 9, wherein
the central conductive layer defines a recess area,
the U-shaped conductive layer is in contact with the recess area of the central conductive layer, and
the U-shaped conductive layer is along an interface between the channel layer and the central conductive layer.

13. The semiconductor device of claim 9, wherein
the bottom portion of the channel layer has rounded corners, and
the U-shaped conductive layer is conformally along the rounded shape of the channel layer.

14. The semiconductor device of claim 13, wherein
the bit line further includes a lower conductive barrier layer on a lower surface of the central conductive layer and an upper conductive barrier layer on an upper surface of the central conductive layer, and
an uppermost surface of the U-shaped conductive layer is in contact with a lowermost surface of the upper conductive barrier layer.

15. The semiconductor device of claim 13, wherein
the bit line further includes a lower conductive barrier layer on a lower surface of the central conductive layer and an upper conductive barrier layer on an upper surface of the central conductive layer, and
a sidewall of the U-shaped conductive layer is in contact with a sidewall of the upper conductive barrier layer.

16. A semiconductor device comprising:
a bit line extending in a first horizontal direction on a substrate and including a first conductive layer containing metal or metal nitride and a second conductive layer containing indium (In);
a mold layer covering the bit line on the substrate and defining a mold opening;
a channel layer on an inner wall of the mold opening, having a bottom portion penetrating the bit line and a sidewall extending in a vertical direction on the inner wall of the mold opening, and comprising an oxide semiconductor material containing In;
a gate insulating layer on the channel layer within the mold opening and comprising a high-k dielectric material;
a word line within the mold opening and on the gate insulating layer and extending in a second horizontal direction intersecting with the first horizontal direction;
a contact layer extended on an upper surface of the channel layer and an upper surface of the gate insulating layer; and
a capacitor structure on the contact layer,
the bottom portion of the channel layer in contact with the second conductive layer, but not with the first conductive layer.

17. The semiconductor device of claim 16, wherein
the first conductive layer comprises any one of tungsten (W), ruthenium (Ru), molybdenum (Mo), tungsten nitride (WN), and titanium nitride (TiN),
the second conductive layer comprises one of indium tin oxide (ITO) and indium oxide (InOₓ), and
the channel layer comprises one of InGaZnOₓ (IGZO) and InZnOₓ (IZO).

18. The semiconductor device of claim 16, wherein
an upper surface and a lower surface of the first conductive layer are flat,
an upper surface of the second conductive layer has a concavo-convex shape, and a lower surface of the second conductive layer has a flat shape, and
a thickness of the first conductive layer in a vertical direction is greater than a thickness of the second conductive layer in the vertical direction.

19. The semiconductor device of claim 16, wherein
the bottom portion of the channel layer has rounded corners, and
the second conductive layer has a U-shape conformally along the rounded shape of the channel layer.

20. The semiconductor device of claim 16, wherein
the bit line defines a recess area, and
the bottom portion of the channel layer fills the recess area of the bit line.
